(19) United States
(12) Patent Application Publication
(10) Pub. No.: US 2010/0110247 A1
(43) Pub. Date: May 6, 2010

(54) IMAGE SENSOR AND METHOD FOR MANUFACTURING THE SAME

(76) Inventor: CHANG HUN HAN, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/610,452

(22) Filed: Nov. 2, 2009

(30) Foreign Application Priority Data
Nov. 6, 2008 (KR) 10-2008-0109805

(51) Int. Cl. H04N 5/335; H01L 31/18

(52) U.S. Cl. 348/294; 438/59; 257/E31.097; 348/E05.091

(57) ABSTRACT

Provided are an image sensor and a method for manufacturing the same. The image sensor comprises a readout circuitry, an electrical junction region, a poly contact, an interconnection, and an image sensing device. The readout circuitry is formed on a first substrate. The electrical junction region is formed in the first substrate. The electrical junction region is electrically connected to the readout circuitry. The poly contact is formed on the electrical junction region. The interconnection is formed on the poly contact. The image sensing device is formed on the interconnection. The image sensing device is electrically connected to the readout circuitry through the interconnection, the poly contact, and the electrical junction region.

### CROSS-REFERENCE TO RELATED APPLICATION

This application claims the benefit under 35 U.S.C. §119 of Korean Patent Application No. 10-2008-0109805, filed Nov. 6, 2008, which is hereby incorporated by reference in its entirety.

### BACKGROUND

The present disclosure relates to an image sensor and a method for manufacturing the same.

Image sensors are semiconductor devices which can convert optical images into electrical signals. Such image sensors can typically be classified as either charge coupled device (CCD) image sensors or complementary metal oxide semiconductor (CMOS) image sensors (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called Airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a “three-dimensional (3D) image sensor”). The photodiode is connected with the readout circuitry through a metal interconnection.

According to a related-art image sensor, there is a limitation in that a charge sharing phenomenon may occur because both the source and the drain of the transfer transistor are heavily doped with N-type impurities. The charge sharing phenomenon may cause reduction of the sensitivity of an output image and generation of image error.

Also, photo charges can not smoothly move between a photodiode and a readout circuitry, causing generation of a dark current and reduction of saturation and sensitivity.

That is, there is a cause of the generation of the dark current in the connection between an upper photodiode and a lower readout circuitry. In addition to the generation of dark current, there are also many limitations in performing processes such as additional processes for reducing an etch damage and a contact resistance that may be generated in formation of a contact.

### BRIEF SUMMARY

Embodiments provide an image sensor and a method for manufacturing the same, which can increase a fill factor while minimizing a charge sharing phenomenon.

Embodiments also provide an image sensor and a method for manufacturing the same, which can minimize a dark current source and inhibit saturation reduction and sensitivity degradation by forming a smooth transfer path of photo charges between a photodiode and a readout circuit.

Embodiments also provide an image sensor and a method for manufacturing the same, which can reduce an etch damage of a contact by forming a poly contact as a contact part connected to an electrical junction region for an ohmic contact and not directly connecting the contact part to the electrical junction region. In addition, dark current characteristics can be reduced by removing an infinite current source due to formation of N+ ohmic contact on the electrical junction region.

In one embodiment, an image sensor comprises: a readout circuitry in a first substrate; an electrical junction region in the first substrate, the electrical junction region being electrically connected to the readout circuitry; a poly contact on the electrical junction region; an interconnection on the poly contact; and an image sensing device on the interconnection.

In another embodiment, a method for manufacturing an image sensor comprises: forming a readout circuitry in a first substrate; forming an electrical junction region in the first substrate, the electrical junction region being electrically connected to the readout circuitry; forming a poly contact on the electrical junction region; forming an interconnection on the poly contact; and forming an image sensing device on the interconnection.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2 through 6 are cross-sectional views of a method for manufacturing an image sensor according to an embodiment.

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

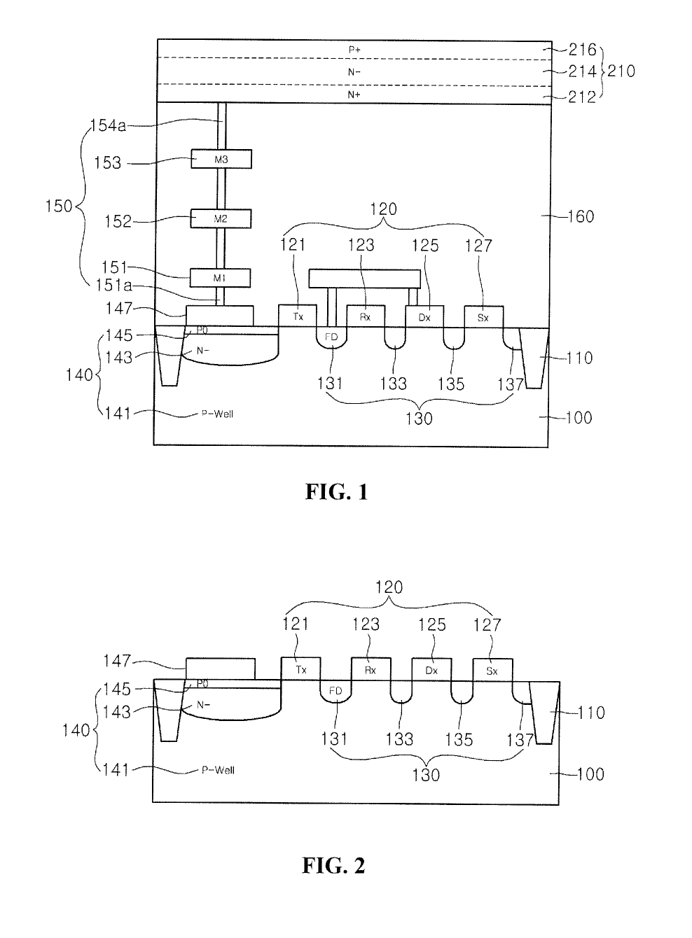

FIG. 1 is a cross-sectional view of an image sensor according to a first embodiment.

An image sensor according to a first embodiment can include: a readout circuitry 120 on a first substrate 100; an electrical junction region 140 in the first substrate 100, the electrical junction region 140 being electrically connected to the readout circuitry 120; a poly contact 147 on the electrical junction region 140; an interconnection 150 on the poly contact 147; and an image sensing device 210 on the interconnection 150.

The image sensing device 210 may be a photodiode, but, without being limited thereto, may be a photogate, or a combination of the photodiode and the photogate. In the embodiments, although it will be described as an example that the photodiode is formed in a crystalline semiconductor layer, the photodiode may be formed in amorphous semiconductor layer.

Unexplained reference numerals in FIG. 1 will be described with reference to the accompanying drawings illustrating a method for manufacturing the image sensor below.

Hereinafter, a method for manufacturing an image sensor according to an embodiment will be described in detail with reference to FIGS. 2 through 6.

First, referring to FIG. 2, a first substrate where a readout circuitry 120 is formed is prepared. For example, an active region is defined by forming a device isolation layer 110 in the second conductive type first substrate 100. The readout circuitry 120 including transistors is formed in the active region.

For example, the readout circuitry 120 may include a transfer transistor (Tx) 121, a reset transistor (Rx) 123, a drive transistor (Dx) 125, and a select transistor (Sx) 127. An ion implantation region 130 including a floating diffusion region 131 and source/drain regions 133, 135 and 137 for each transistor may be formed.

The method for manufacturing an image sensor may include forming the electrical junction region 140 in the first substrate 100, and forming a poly contact 147 on the electrical junction region 140. The poly contact 147 is formed for connection of the electrical junction region 140 to an interconnection 150 (see FIG. 1), and can directly contact the electrical junction region 140.

The electrical junction region 140 may be a P-N junction 140, but is not limited thereto. For example, the electrical junction region 140 may include a first conductive type ion implantation layer 143 formed on a second conductive type well 141 or a second conductive type epitaxial layer, and a second conductive type ion implantation layer 145 formed on the first conductive type ion implantation layer 143. For example, as shown in FIG. 2, the P-N junction 140 may be a P0(145)/N-(143)/P-(141) junction, but is not limited thereto. The first substrate 100 may be a second conductive type, but is not limited thereto.

According to an embodiment, the device is designed to provide a potential difference between the source and drain of the transfer transistor (Tx), thereby enabling the full dumping of photocharges. Accordingly, the photocharges generated in the photodiode may be dumped to the floating diffusion region to increase the sensitivity of an output image.

That is, as described in FIG. 2, the electrical junction region 140 may be formed in the first substrate 100 including the readout circuit 120 to provide a potential difference between the source and drain of the transfer transistor (Tx) 121, thereby enabling the full dumping of photocharges.

Accordingly, unlike a related-art where a photodiode is simply connected to an N+ junction, this embodiment can avoid saturation reduction and sensitivity degradation.

Thereafter, a poly contact 147 is formed between the photodiode and the electrical junction region to make a smooth transfer path of photocharges, thereby minimizing a dark current source and preventing saturation reduction and sensitivity degradation.

For this, the poly contact 147 may be formed for an ohmic contact on the surface of the P0/N-/P-junction 140.

According to this embodiment, the poly contact 147 may be formed at a P0/N-/P-junction 140 for an ohmic contact. The poly contact 147 can be formed instead of a direct first metal contact (M1C) 151a because a leakage source may occur in a process of forming the M1C contact 151a. This is because an electric field (EF) may be generated over the Si substrate surface due to an operation while a reverse bias is applied to P0/N-/P-junction 140. A crystal defect generated in the electric field while the contact (M1C) is formed may become a leakage source.

Accordingly, embodiments can reduce an etch damage of a contact by forming a poly contact as a contact part connected to an electrical junction region for an ohmic contact and not directly connecting the contact part (such as M1C) to the electrical junction region, and can reduce dark current characteristics by removing an infinite current source due to formation of an N+ ohmic contact region on the electrical junction region.

The poly contact 147 may be formed after the readout circuitry 120 and the electrical junction region 140 are formed. For example, after the readout circuitry 120 is formed, the electrical junction region 140 and the source/drain 130 may be formed through an ion implantation. Thereafter, the poly contact 147 may be formed.

The poly contact 147 may be formed in concurrence with the readout circuitry after the electrical junction region 140 is formed. That is, an etching process for forming the poly contact 147 may be performed in concurrence with an etching process for forming the transistor gates of the readout circuitry 120.

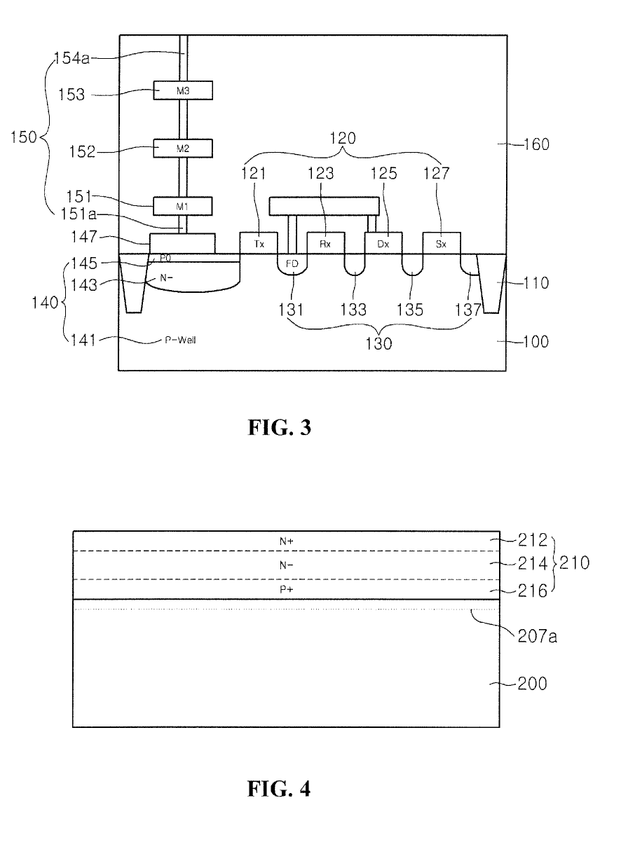

Next, referring to FIG. 3, an interlayer dielectric 160 is formed, and an interconnection 150 may be formed therein. The interconnection 150 may include the first metal contact 151a, a first metal 151, a second metal 152, a third metal 153, and a fourth metal contact 154a, but embodiments are not limited thereto.

The poly contact 147 may be formed to have a smaller width than the electrical junction region 140 and a greater width than the interconnection 150, such as a greater width than the first metal contact 151a. For example, according to one embodiment, the width of the poly contact 147 may be formed to have a width three times greater than the width of the first metal contact 151a and 0.8 times smaller than the width of the electrical junction region 140. Thus, a gate poly is formed wide enough to form an ohmic contact. Also, an etch damage of a contact can be reduced by not directly connecting the contact part (such as the first metal contact 151a) to the electrical junction region, and dark current characteristics can be reduced by removing an infinite current source due to formation of an N+ ohmic contact region for the first metal contact 151a on the electrical junction region.

Referring to FIG. 4, a crystalline semiconductor layer (not shown) can be formed on a second substrate 200, and a photodiode 210 can be formed in the crystalline semiconductor layer. The first embodiment shows the photodiode 210 being formed in the crystalline semiconductor layer of a second substrate and then bonded to the first substrate. Thus, an image sensing device may adopt a three-dimensional image sensor positioned at an upper side of the readout circuitry, thereby increasing a fill factor, and may be formed in a crystalline semiconductor layer, thereby inhibiting a defect in the image sensing device.

For example, a crystalline semiconductor layer is formed on the second substrate 200 through an epitaxial process. Thereafter, hydrogen ions are implanted into a boundary region between the second substrate 200 and the crystalline semiconductor layer to form a hydrogen ion implantation layer 207a. In another embodiment, the implantation of the hydrogen ions may be performed after an ion implantation for forming the photodiode 210.

Next, the photodiode 210 is formed through an ion implantation into a crystalline semiconductor layer. For example, a second conductive type layer 216 is formed at a lower part of the crystalline semiconductor layer. For example, a high-concentration P-type conductive layer 216 may be formed at a lower part of the crystalline semiconductor layer by implanting ions into substantially the whole surface of the second substrate 200 using a blanket implant without a mask. For example, the second conductive type layer 216 may be formed with a junction depth of less than about 0.5 μm from the bottom surface of the crystalline semiconductor layer.

Next, a first conductive type layer 214 is formed on the second conductive type layer 216. For example, a low-concentration N-type conductive layer 214 may be formed on the second conductive type layer 216 by implanting ions into the whole surface of the second substrate 200 using a blanket implant without a mask. The low-concentration first conductive type layer 214 may be formed with a junction depth of about 1.0 μm to about 2.0 μm.

The first conductive type layer 214 is formed to have a thickness greater than that of the second conductive type layer 216, thereby increasing a charge storing capacity. That is, the capacity capable of accommodating photoelectrons may be enhanced by increasing the thickness of the first conductive type layer 214 to thereby expand the volume thereof.

Next, the method for manufacturing an image sensor may further include forming a high-concentration first conductive type layer 212 on the first conductive type layer 214. For example, the high-concentration first conductive type layer 212 may be formed with a junction depth of less than about 0.05 μm to about 0.2 μm. For example, the high-concentration N+ type conductive layer 212 may be further formed on the first conductive type layer 214 by implanting ions into the whole surface of the second substrate 200 using a blanket implant without a mask, thereby contributing to an ohmic contact.

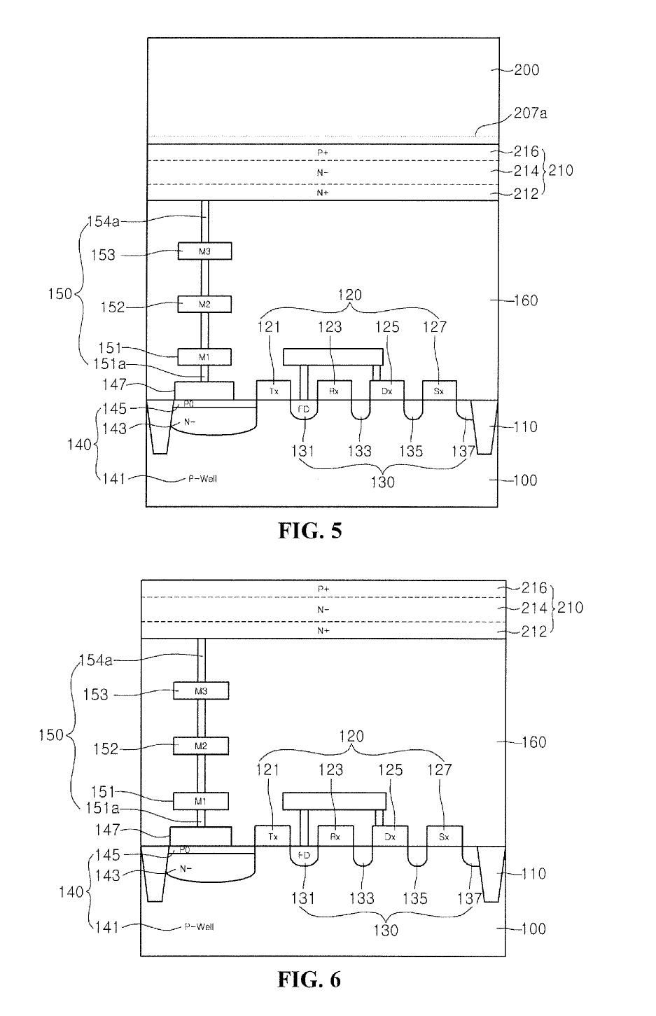

Next, referring to FIG. 5, the first substrate 100 and the second substrate 200 may be bonded to each other such that the photodiode 210 contacts the interconnection 150. In this case, the surface energy at the bonded surfaces may be increased by plasma activation before the bonding of the first substrate 100 and the second substrate 200. In another embodiment, an insulating layer or a metal layer may be interposed between the bonded surfaces to enhance a bonding strength.

Next, referring to FIG. 6, the second substrate 200 may be heat-treated such that the hydrogen ion implantation layer 207a changes into a hydrogen gas layer (not shown), and the second substrate 200 can be cleaved to leave the photodiode 210 remaining on the first substrate.

Thereafter, etching and deposition processes for separating the photodiode 210 into pixels may be performed to fill interpixel insulating layers (not shown) in etched portions of pixels, separating the photodiode 210 into pixels.

The image sensor and the method for manufacturing the same in accordance with embodiments are designed such that there is a potential difference between the source and drain of the transfer transistor (Tx), thereby enabling the frill dumping of a photo charge.

Also, a charge connection region may be formed between a photodiode and a readout circuit to create a smooth transfer path of a photo charge, thereby minimizing a dark current source and inhibiting saturation reduction and sensitivity degradation.

Furthermore, the image sensor and the method for manufacturing the same can reduce an etch damage of a contact by forming a poly contact as the contact part connected to an electrical junction region for an ohmic contact and not directly connecting the regular contact part to the electrical junction region, and can reduce dark current characteristics by removing an infinite current source due to formation of N+.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry on a first substrate;
an electrical junction region in the first substrate, the electrical junction region being electrically connected to the readout circuitry;
a poly contact on the electrical junction region;
an interconnection on the poly contact; and
an image sensing device on the interconnection.

2. The image sensor according to claim 1, wherein the poly contact has a width greater than that of a contact of the interconnection and smaller than that of the electrical junction region.

3. The image sensor according to claim 1, wherein the readout circuitry comprises a transistor having a source and a drain, wherein the electrical junction region is disposed at the source of the transistor to provide a potential difference between the source and the drain of the transistor.

4. The image sensor according to claim 3, wherein the transistor is a transfer transistor, and wherein an ion implantation concentration of the source of the transistor is lower than an ion implantation concentration of a floating diffusion region at the drain of the transistor.

5. A method for manufacturing an image sensor, comprising:
forming a readout circuitry on a first substrate;
forming an electrical junction region in the first substrate, the electrical junction region being electrically connected to the readout circuitry;
forming a poly contact on the electrical junction region;
forming an interconnection on the poly contact; and
forming an image sensing device on the interconnection.

6. The method according to claim 5, wherein the forming of the poly contact comprises forming the poly contact to have a width greater than that of a contact of the interconnection and smaller than that of the electrical junction region.

7. The method according to claim 5, wherein forming the readout circuitry comprises forming transistors, wherein the forming of the poly contact is performed after the forming of the transistors of the readout circuitry.

8. The method according to claim 5, wherein the readout circuitry comprises a transistor having a source and a drain, wherein the electrical junction region is disposed at the source of the transistor to provide a potential difference between the source and the drain of the transistor.

9. The method according to claim 8, wherein the transistor is a transfer transistor, and wherein an ion implantation concentration of the source of the transistor is lower than an ion implantation concentration of a floating diffusion region at the drain of the transistor.
